(19) United States
(12) Patent Application Publication
(10) Pub. No.: US 2006/0276038 A1
(43) Pub. Date: Dec. 7, 2006

(54) Thermal desorption of oxide from surfaces

(76) Inventors: Arthur F. Pun, Tallahassee, FL (US); Jian-Ping Zheng, Tallahassee, FL (US)

Correspondence Address: MILES & STOCKBRIDGE PC, 1751 PINNACLE DRIVE, SUITE 500, MCLEAN, VA, 22102-3833, US

(21) Appl. No.: 11/143,739

(22) Filed: Jun. 3, 2005

(51) Int. Cl. H01L 21/302; H01L 21/461

(52) U.S. Cl. 438/689

(57) ABSTRACT

Disclosed is a method for removing a layer of native oxide from a surface of a substrate without altering the smoothness of the substrate surface comprising: 1) depositing on the substrate surface a thin sacrificial layer of the substrate surface material, having a thickness sufficient to react with all of the native oxide when the substrate surface is subjected to thermal oxide desorption conditions, and 2) subjecting the substrate to thermal oxide desorption conditions for a time sufficient for all of the native oxide layer to react with the deposited sacrificial layer of substrate material to form volatile reaction products and evaporate from the substrate surface.

This invention was made with Government support under National Science Foundation Grants Nos. 9903460 and 0076485. The U.S. Government has certain rights in this invention.

### FIELD OF THE INVENTION

This invention is related to methods and systems for thermally removing oxide layers from surfaces without affecting the smoothness of the underlying surface.

### BACKGROUND OF THE INVENTION

Many industries are involved with the fabrication of articles on the surfaces of which “native oxide” form, either from the reaction of ambient oxygen with one or more of the materials forming the surfaces of the fabricated article to form an oxide layer thereon or by the intentional oxidation of the surface to form a protective oxide layer. It is often necessary to remove this native oxide layer, whether intentionally formed or nor not, from the article before it can be put to use or further processed. Numerous methods and systems have been proposed heretofore for removing these oxide layers. Most often, however, these prior art methods and systems leave the underlying surface altered in some way due primarily to the harsh measures and conditions required to remove the oxide layer.

One such area where the removal of native oxide layers has proven to be extremely problematic is the semiconductor industry. Typically, in this industry semiconductor wafers composed of silicon, group III-V alloys and the like are immediately covered with a protective native oxide layer formed, e.g., in a UV/ozone system to a thickness of between 1-2 nm [V. Palmero, and D. Jones, Mater. Sci. and Eng. B88, 220 (2002). These native oxide layers are formed to pacify the wafer surfaces and protect them from contaminating environments. They exhibit inferior electrical properties and interfere with the growth of electronic layers on the wafer, however, and must be removed prior to semiconductor device manufacture.

There currently exist several conventional methods for the removal of this native oxide layer. Ion milling is one mechanical technique in which the removal of surface material is accomplished thru ion bombardment of the substrate resulting in a pristine surface, but contains several drawbacks including its high cost, complexity, and low throughput [Salimian et al., J. Appl. Phys., 70, 3970 (1991)].

Another technique utilized in native oxide removal is the use of chemical etching, whereby the oxide is removed thru chemical processes reactions with such materials as fluorinated and chlorinated species, sulfuric acid, or hydrogen peroxide. One such process as described in 1998 (U.S. Pat. No. 6,117,796) utilizes a liquid composition containing fluoride compounds for etching of the oxide layer. Another (U.S. Pat. App. 20010031556) utilize a vaporous solution of hydrofluoric acid. Differing slightly, Shields (U.S. Pat. No. 6,239,006) utilizes a fluorinated plasma for oxide removal. However, all of these methods involve the use of liquid, vaporous, or plasma states for chemical etching requiring significant amounts of hazardous materials.

Another commonly utilized method is thermal desorption of oxide species by the heat treatment of the substrate material. This method is disadvantageous, however, in that it leads to an increase of surface roughness in the treated wafer because of non-homogenous reactions between the oxide layer and the wafer surface resulting in the creation of voids or pits in the wafer surface. These pits and voids in the wafer surface affect the electrical characteristics of the wafer and seriously interfere with the manufacture of devices therefrom. For example, surface roughness significantly affects modern devices, such as metal-oxide semiconductor field-effect transistors, by causing carrier scattering in the active regions of the devices. Moreover the pits and voids created by thermal desorption of native oxides cause the generation of stacking faults, affecting the subsequent building of devices such as laser diodes. Surface roughness also affects such parameters in the wafer as surface scattering and threshold voltages. The formation of surface pits has made it necessity for the manufacturer to grow micrometer-thick homo epitaxial buffer layers intended to smoothen the surface. However, this expedient suffers from several deficiencies, including the utilization of significant time and material to deposit the buffer layer, which ultimately does not ultimately guarantee the elimination of propagating stacking faults.

In the case of GaAs, a typical Group III-V alloy wafer, the preferential evaporation of arsenic from the surface at elevated temperatures due to its higher vapor pressure, results in a gallium rich stochiometry in the wafer surface. Secondly, surface pits are created in the wafer surface due to a thermally driven reaction between the oxide species and the underlying gallium arsenide substrate. A variety of different techniques were developed to prevent arsenic evaporation. One approach (U.S. Pat. No. 4,226,667) used an inert capping layer disposed on the native oxide layer such that it prevents the evaporation of arsenic. U.S. Pat. No. 4,312,681 disclosed utilizing the presence of other group III-V semiconductors with the purpose of creating an over-pressure of the group V element to inhibit evaporation of that species. U.S. Pat. No. 4,879,259 utilized a more direct method by introducing an arsenic atmosphere with trimethylarsenic as the source. This process of introducing arsenic overpressures has subsequently been used during the heat treatment of gallium arsenide prior to molecular beam epitaxy growth utilizing a molecular beam of arsenic.

The second, more damaging problem, i.e., the formation of surface pits, with typical depths and widths of 520 nm and 20-200 nm, respectively, at the high temperatures necessary for thermal desorption of oxide species has not been solved. Both Yamada et al. in Surface Science, vol. 339, pg. 1914-1918, (1995) and Guillen-Cervantes in Thin Solid Films, vol. 373, pg. 159-163, (2000) and others have detailed the creation of these surface pits.

The heating of GaAs to temperatures necessary to thermally desorb the native oxide layer varies with oxide thickness and wafer preparation, but has been found to generally be in the range of 550° C. to 700° C. The native oxide layer thickness increases with time even while stored in epiready-compatible inert atmosphere packaging due to transfer oxidation, and has been found to vary from 0.7 nm to 4.3 nm This heating of GaAs native oxides results in oxideinduced etching associated with a phase transition of oxide species into more volatile compounds The etching behavior can be understood by examining the constituents of the native oxide layer, and their thermal decomposition routes. The native oxide layer has been shown to consist of As, As₂O₃, Ga₂O and Ga₂O₃ close to the wafer interface, and As₂O₅ and GaAsO₄ nearer to the surface. Of these, only Ga₂O₃, As₂O₃, and As₂O₅ are stable isolatable oxidation states of Ga and As, with As₂O₅ being less abundant due to its higher oxidation state. Further, Ga₂O and GaAsO₄ are believed to be major constituents of the native oxides. Upon heating, Ga₂O is volatile and evaporates, whereas GaAsO₄ and As₂O₅ decompose according to the equations:
2GaAsO₄=>Ga₂O₃+As₂O₃+O₂(↑) (1)
3As2O₅+4GaAs=>3As₂O₃+2Ga₂O₃+2As₂(↑) (2)
It has been shown that upon heating to <300° C., all the constituents, with the possible exception of Ga₂O, decompose into either Ga₂O₃ or As₂O₃. Upon further heating, the following reaction occurs between 320° C. and 400° C.:
As₂O₃+2GaAs=>Ga₂O₃+2As₂(↑) (3)
while continuing heating to temperatures n excess of 500° C. results in the following reaction:
Ga₂O₃+4GaAs=>3Ga₂O(↑)+2As₂(↑) (4)

These three reactions, (2), (3) and (4), not only decompose the remaining oxide layer constituents into volatile compounds that are evaporated from the wafer surface, but utilize bulk GaAs material resulting in the etching of the wafer surface in the form of surface pits, characterized by 20 to 500 nm widths, 5 to 20 nm depths, and a densities of 10⁸ to 10¹⁰ cm².

Asaoka in Journal of Crystal Growth, vol. 251, pg 40-45, (2003) developed a system in which while at the temperature of 440° C., direct gallium molecular beam irradiation was utilized in an effort to minimize the usage of bulk GaAs from the substrate by providing another material source. However, this solution requires the usage of temperatures above those necessary to drive chemical reaction (1) due to the near unity sticking coefficient of gallium at low temperatures on GaAs.

Similar problems arise when attempting to thermally desorb native oxides from silicon wafer surfaces utilizing heat treatment in a reduced or non-reactive atmosphere. This method, however, suffers from the thermally driven reaction between constituents of the oxide species and the underlying Si substrate leading to damage to the substrate in the form of surface roughening. This can be explained by examining the following reaction which occurs at approximately 800° C.:
Si+SiO₂=>2SiO(↑) (5)

As noted from this equation, the stable Si-oxide reacts, consuming bulk Si to produce the unstable SiO reaction product, which is evaporated at these temperatures. This thermally driven chemical reaction for the evaporation of oxide species utilizes bulk Si material in an inhomogenous way such that the resulting substrate surface is characterized by either voids or central silicon columnar structures. The kinetics of this surface damage and the necessary temperature for this reaction to occur is strongly dependent upon the chemical method of oxide formation, its thickness, surface contaminants, and the presence of excess Si atoms near the Si/SiO₂ interface, and has been extensively studied. These changes in surface morphology are dependent on equation (5) and are thus reliant on the presence of SiO, within the oxide layer. It is desirable to minimize this surface roughness due to its effect on electron mobility, which is currently accomplished by growing micron-thick homoepitaxial buffer layers after desorption.

These are but 2 examples of substrate surfaces overlaid with native oxide surfaces that suffer from the above-noted disadvantages when thermal desorption is utilized to remove the oxide layer. Numerous and varied substrates are similarly affected when the thermal desorption of native oxides from their surfaces is attempted due to the reactions between the native oxide species and the underlying material.

It is an object of the invention to provide a method for the thermal desorption of native oxides from the surfaces of substrates without significantly affecting the smoothness or other physical or chemical characteristics of the underlying surface.

### SUMMARY OF THE INVENTION

The above and other objects are realized by the present invention, one embodiment of which relates to a method for removing a layer of native oxide from a surface of a substrate without significantly altering the smoothness of the substrate surface, i.e., its surface morphology, the method comprising:

1) depositing on the substrate surface a thin sacrificial layer of the substrate surface material, the deposited sacrificial layer substantially covering the native oxide layer, the deposited sacrificial layer having a thickness sufficient to react with all of the native oxide when the substrate surface is subjected to thermal oxide desorption conditions and the deposition being conducted under conditions that do not significantly affect the chemical or physical properties of the substrate or the substrate surface, and

2) subjecting the substrate to thermal oxide desorption conditions for a time sufficient for all of the native oxide layer to react with the deposited sacrificial layer of substrate material to form volatile reaction products and evaporate from the substrate surface.

Although the following description of the invention details the method as applied to various semiconductor substrates, it will be understood that the invention is equally applicable, without undue experimentation or the exercise of inventive faculties, utilizing the principles of the invention as explained herein, to the thermal desorption of native oxides from any suitable substrate surface.

### BRIEF DESCRIPTION OF THE INVENTION

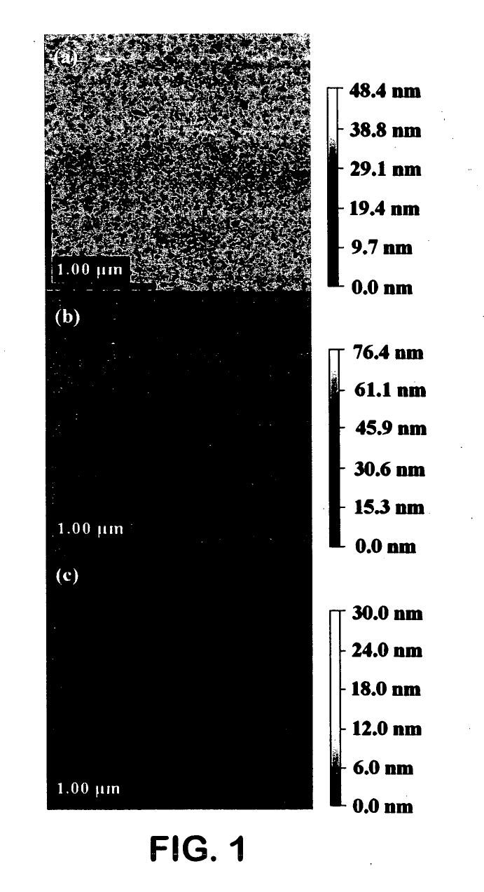

FIGS. 1, 3, 6, 9 and 10 depict atomic force microscopy results produced by the method of the invention.

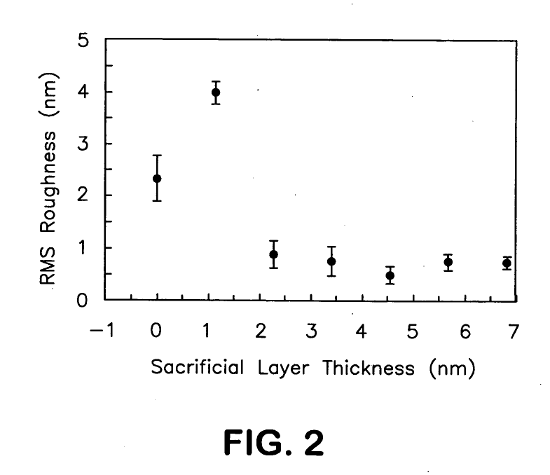

FIGS. 2, 4 and 7 depict RMS roughness for wafers treated according to the method of the invention.

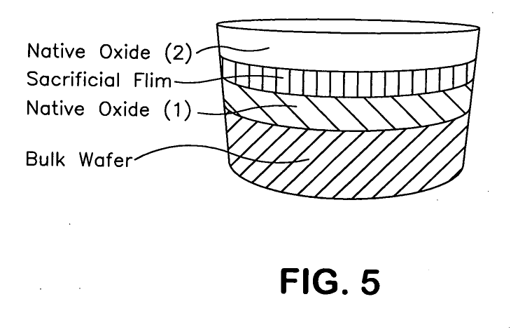

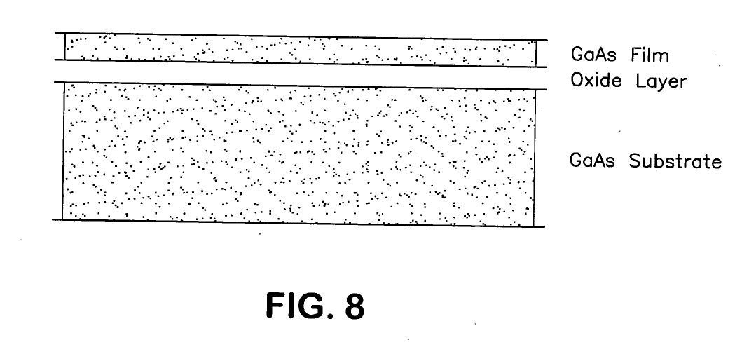

FIGS. 5 and 8 are side elevational views of wafer substrates subjected to the method of the invention.

### DETAILED DESCRIPTION OF THE INVENTION

The present invention is predicated on the discovery that if a sacrificial layer comprising the material of which the substrate surface is fabricated is deposited on the native oxide and the substrate heated to oxide-desorption temperatures, the native oxide will preferentially react with the sacrificial deposit until the oxide species are exhausted leaving the morphology, i.e., smoothness, of the underlying substrate surface substantially unaltered.

### Example 1

The following is a description of the utilization of the method of the present invention to thermally desorb a native oxide layer from a GaAs wafer surface. Due to its superior electron transport characteristics and direct band-gap structure, gallium arsenide (GaAs) is one of the most extensively studied compound semiconductors. As supplied by wafer manufacturers utilizing a well-established procedure, a sacrificial UV/ozone native oxide layer is provided over the wafer substrates as a passivation layer and protection method from such contaminants as carbon.

According to the method of the invention by feeding reactions (2), (3) and (4) with additional, sacrificial GaAs the substrate is less damaged. This is accomplished by depositing a thin GaAs layer directly onto the native oxide surface prior to thermal treatment. The thickness of this thin layer (d_{film}) is dependent on both the oxide thickness and the ratio of Ga₂O:GaAs)₄:As₂O₃:As₂O₅:Ga₂O₃ and can be calculated by combining equations (1)-(4):

$${d}_{film} = \frac{{d}_{oxide} \times {m}_{GaAs}}{{P}_{GaAs}} \times [ \frac{10 \times {p}_{{As}_{2} {O}_{5}} \times {n}_{{As}_{2} {O}_{5}}}{{m}_{{As}_{2} {O}_{5}}} + \frac{6 \times {p}_{{As}_{2} {O}_{3}} \times {n}_{{As}_{2} {O}_{3}}}{{m}_{{As}_{2} {O}_{3}}} + \frac{4 \times {p}_{{Ga}_{2} {O}_{3}} \times {n}_{{Ga}_{2} {O}_{3}}}{{m}_{{Ga}_{2} {O}_{3}}} + \frac{5 \times {p}_{{GaAsO}_{4}} \times {n}_{{GaAsO}_{4}}}{{m}_{{GaAsO}_{4}}} ] \qquad ( 6 )$$

where n, m, and p are the volumetric percentage, molecular weight and mass density of each species, respectively, and d_{oxide} is the total oxide thickness.
Furthermore, because it is a sacrificial layer, the structure and deposition method of the thin film is inconsequential, although uniformity of thickness is paramount.

For this example, a pulsed laser deposition system with a base pressure of ˜10⁻⁷ Torr was utilized to deposit an amorphous GaAs layer, as shown by reflection high-energy electron diffraction (RHEED), onto a 2 nm native oxide layer (as specified by the manufacturer) present on n-type GaAs(100) substrate at a temperature of ˜50° C. The sample was subsequently heated to a temperature of 550° C. and held at that temperature for 30 minutes, during which time RHEED was utilized to monitor the oxide desorption process. It had been previously found that, qualitatively, having the electron beam incident on the sample during heating, rather than after desorption of the oxides, makes no difference in the final RHEED pattern. Following this heating, the sample was rapidly cooled to reduce post process surface modification and removed for ex-situ examination under contact mode atomic force microscopy (AFM).

FIG. 1(a) shows a 2.5 μm AFM scan that illustrates the typical surface morphology from a typical prior art method of heating an epiready GaAs wafer to 550° C. to desorb the protective native oxide layer. The surface is characterized by pits with an observed density of 10¹⁰ cm² and an average depth and width of approximately 10 nm and 50 nm, respectively. FIG. 1(b) shows the typical morphology obtained from a GaAs substrate subjected to the above-described method wherein a 1.1 nm thick amorphous GaAs layer was deposited onto the native oxide prior to heating. The film contains a reduced density of pits, 2×10⁹ cm², with an increased average depth and width of approximately 30 nm and 100 nm, respectively. Finally, the typical morphology obtained where the thickness of the sacrificial layer was 4.6 nm, is shown in FIG. 1 (c), which evidences the virtual absence of any surface pits.

For a more quantitative analysis, samples were analyzed for varying sacrificial layer thicknesses, in which the root-mean-square (RMS) roughness was calculated, with the results plotted in FIG. 2. From the resulting untreated surface roughness value of 2.3 nm, the roughness initially increases with sacrificial layer thickness to a value of 4.0 nm, as shown in the corresponding FIGS. 1(a) and 1(b). Further sacrificial layer thickness results in a drastic decrease in the roughness, to a minimum value of 0.5 nm for a 4.6 nm thick deposited film. Any increase in film thickness past this point results in a slight increase of the roughness to a value of 0.75 nm. The initial drastic increase in roughness to 4.0 nm, is conceivably caused by the compounding of several factors. First, the thermal desorption process already yields a value of 2.3 mm, as indicated by the normally desorbed sample, though the total contribution to the sample subjected to the 1.1 nm sacrificial film could be greater or less, depending on the exact thermal desorption kinetics. However, additional factors may also contribute to this initial roughening, including incomplete coverage due to the thin nature of the sacrificial film instigating local pit formation at discrete locations acting as a sink for the following desorption process. Additionally, surface irregularities of the sacrificial film may cause transfer roughness through the oxide onto the wafer surface, which perhaps contributes to this initial roughening to 4.0 mm for the 1.1 mm sacrificial film sample. It should be pointed out that it is believed that reaction (2), (3) and (4) have a higher affinity toward the sacrificial layer than the substrate underneath the oxide layer due to the different crystalline structure. RHEED results indicate no difference between regularly desorbed samples and those subjected to methods of the invention employing sacrificial layer thicknesses up to 4.6 mm, and are consistent with RHEED patterns obtained by Hey et al., J. Cryst. Growth, 154, 1 (1995), indicating the proposed method does not significantly alter the surface crystalline structure. To demonstrate this, a sample subjected to a 4.6 mm sacrificial film treatment was subsequently utilized for homoepitaxial growth by pulsed laser deposition and shown to yield a Ga-rich (4×2) reconstruction. The Ga-rich construction is believed to be a result of utilizing a temperature above the congruent sublimation temperature of GaAs and the type of deposition performed, as indicated by obtaining similar results for untreated samples grown in the same manner. Further treatment past the optimum value of 4.6 mm results in a slight decrease in the specular spot-to-background RHEED intensity ratio, indicating excess diffuse scattering caused by excess surface GaAs, as further corroborated by the slight increase in surface roughness as observed by AFM.

The epiready GaAs wafers utilized in this study were passivated with an ozone grown native oxide layer, of which the following assumptions are made of densities” 5.31 g/cm³, 5.88 g/cm³, 3.74 g/cm³ and 4.225 g/cm³ for GaAs, Ga₂O₃, As₂O₃, and GaAsO₄, respectively, that it is comprised of only Ga₂O, GaAsO₄, As₂O₃, and Ga₂O₃ with minimum As₂O₃, and a total native oxide thickness of 20 Å as specified by the wafer manufacturer. From these assumptions, the calculated Ga₂O percentage is between 17%-33% from equation (5) for any possible combination of volumetric ratio for different oxide components. Additionally, one can readily calculate the optimum sacrificial layer thickness value of 4.6±0.5 nm assuming the native oxide is comprised of 25% Ga₂O, indicating that when subjected to an optimum method of the invention, a majority of the native oxide is forced to react with the deposited thin film instead of etching the wafer surface.

In conclusion, a novel method for reducing substrate damage during the thermal desorption of an oxide layer is presented, which is fully implementable in most systems, requiring only the ability to heat the substrate, deposit gallium arsenide, and lastly the ability to create either vacuum conditions or a non-reactive atmosphere. This method, which requires only the deposition of a very thin film (<5 nm), enables a reduction in the thickness of, if not elimination of the current technique of applying a micron-thick buffer layer to smoothen the substrate surface. This is particularly important for process conditions where desorption under an arsenic flux is not feasible.

### Example 2

Following is a description of the method of the present invention applied to reduce surface roughening by feeding reaction (5), above, with additional Si, such that the substrate is less damaged. This is accomplished by depositing a very thin Si layer directly onto the native oxide surface prior to thermal treatment. The required thickness (d_{film}) of this thin layer is dependent on both the oxide thickness and its SiO₂ incorporation, and can readily be calculated from equation (5) as:
d_{film}=0.48×d_{oxide}×n (7)
where d_{oxide} is the total oxide thickness and n is the percentage of SiO₂ in the native oxide (assuming densities of 2.3 g/cm³ and 2.4 g/cm³ for amorphous silicon and SiO₂, respectively).

Furthermore, the structure and deposition method of the thin film is inconsequential, however the uniformity of thickness and completeness of coverage are paramount. Problems circumvented in the method of the invention by depositing a solid sacrificial film of calculated thickness prior to heating thus reducing the possibility of excess polycrystalline material following heating.

For this study, a pulsed laser deposition system with a base pressure of ˜10⁻⁷ Torr was utilized to deposit an amorphous Si layer, as shown by reflection high-energy electron diffraction (RHEED), onto a 2 nm native oxide layer (as measured by ellilpsometry) present on a n-type Si(100) substrate at a temperature of 200° C. The sample was subsequently heated to a temperature of 850° C. and held at that temperature for 30 minutes, during which time RHEED was utilized to monitor the oxide desorption process. Following this heating, the sample was rapidly cooled to reduce post process surface modification, then removed for ex-situ examination under contact mode atomic force microscopy.

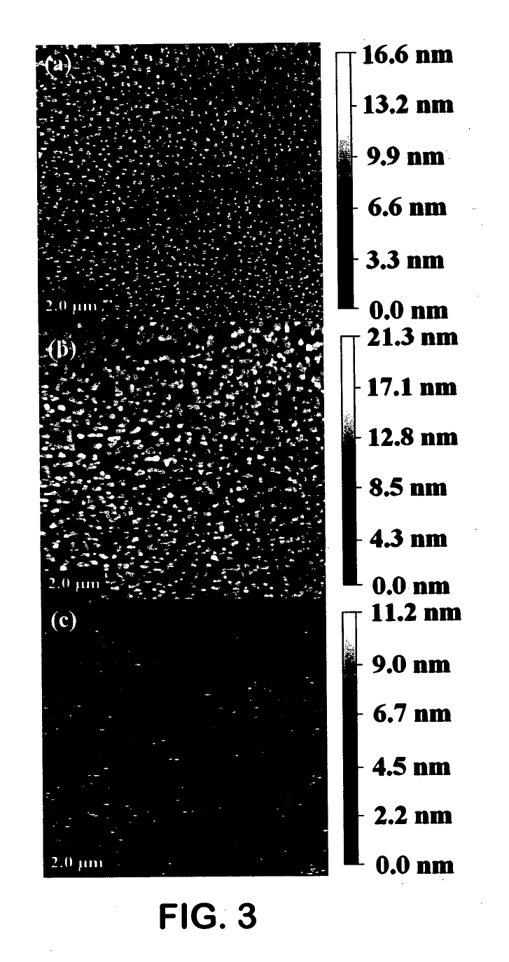

FIG. 3(a) shows the typical sample surface morphology obtained from heating an untreated substrate, characterized by large Si structures as a result of reaction (5) etching away at the substrate surface. For a sample treated with a 0.28 nm thick amorphous Si layer prior to heating, the size of these silicon structures is increased by a factor of −2, as shown in FIG. 3(b). FIG. 3(c) illustrates a sample which has been subjected to a 0.43 nm thick Si film prior to heating. The resulting surface morphology is significantly smoother as a result of being subjected to the method of the invention. For all three samples shown in FIG. 1, RHEED indicated a single crystal surface with a two-fold reconstruction in the <110> direction.

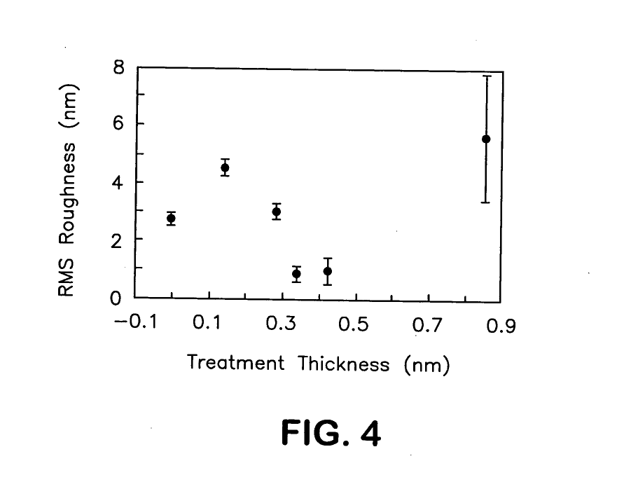

For a more quantitative analysis, samples were analyzed for a range of treatment thickness, with the resulting final root-mean-square (RMS) roughness calculated as plotted in FIG. 4. For an untreated substrate heated to desorb the native oxide layer, corresponding to FIG. 3(a), the RMS roughness was found to be 2.7 nm, far greater than the ˜0.2 nm value typical for as received Si wafers. Interestingly enough, viewed as a function of treatment thickness the roughness initially increases to a peak value of ˜4.5 nm, corresponding to a deposited film thickness of 0.14 nm. This initial increase can be rationalized as due to a contribution of several initial compounding factors. Firstly, the thermal desorption process has been shown, for the untreated sample, to contribute significantly to surface roughening. Further, due to the very thin sacrificial film thickness (0.14 nm), incomplete coverage of the native oxide may initially enhance surface roughening by instigating local area oxide desorption prior to other portions of the wafer. Lastly, such a thin film is less than one monolayer in thickness, so that although the RHEED indicated coverage by an amorphous layer, it is unlikely to have completely covered the wafer, at least homogenously. However, these effects are reduced as the deposited film thickness is increased to 0.34 nm, wherein the RMS surface roughness decreases sharply to a value of 0.84 nm. The further increase of the deposited film to a thickness of 0.85 nm shows an increasing trend expected from an excess of sacrificial silicon for complete reaction with the oxide layer.

For the sample with a 0.85 nm Si sacrificial film, RHEED indicated a mixed poly crystalline/crystalline surface after reacting an elevated temperature, thus indicating the presence of excess un-reacted silicon left on the surface; this would account for the general increase in surface roughness. As the deposited film thickness is decreased, an optimum value of 0.34 nm is found, in which reaction (5) mainly occurs between native oxide and Si sacrificial layers and is found to minimally etch the substrate surface. The further decrease in film thickness consequently reduces the available free silicon necessary to desorb the oxide species resulting in the utilization of bulk silicon from the substrate. By employing this technique to prematurely inhibit the reaction between the native oxide and silicon substrate, one can readily document the oxide desorption process. From FIG. 3, it can be deduced that, in this instance, wide shallow voids are formed on the surface, and continue to grow in such a way that rounded 3D islands are formed. Progressively, these voids continue to grow in such a manner that the islands also grow, until such a point that all the SiO₂ has reacted.

From FIG. 4, the optimum thickness of the sacrificial film resulting in minimum surface roughness is found to be 0.34 nm. Based on equation (B), the calculated corresponding SiO₂ thickness is 0.71 nm, which is significantly less than the measured oxide thickness of 2 mm. However, native oxides are also comprised of SiO, which can be evaporated without the consumption of bulk silicon. This small proportion of SiO₂ is expected in air-formed native oxides due to the lower oxidation conditions. Conversely, after deposition of the silicon film, any re-oxidation would cause an increase in the optimum thickness.

Thus, the method of the invention for reducing substrate damage during the thermal desorption of an oxide layer is fully implementable in most systems, requiring only the ability to heat the substrate, deposit Si, and lastly the ability to create either vacuum conditions or a non-reactive atmosphere. This method, which requires only the deposition of a very thin film (<1 nm), enables a reduction of the thickness of, if not the elimination of the current technique of applying a thick buffer layer (several microns thick) to smoothen the substrate surface after oxide desorption.

### Example 3

This example describes an alternative embodiment of the method of the invention for desorbing native oxides from silicon wafer surfaces. A tri-layer surface pacification structure is proposed in an effort to stifle inherent surface roughening caused during the thermal desorption of silicon native oxides. The method involves a tri-layer structure consisting of two native oxides enclosing a thin sacrificial silicon layer. Upon heating the oxides decompose via reaction with the enclosed silicon. Experimental AFM results indicate significant reduction in surface roughness from a RMS value of 2.5 nm, for the normally desorbed sample, to 0.44 nm as the minimally obtained value, and 0.88 nm as the optimum value retaining a highly single crystal surface.

Therefore, to inhibit the inherent surface roughening caused during desorption, an additional sacrificial source of silicon is directly deposited onto the native oxide at comparatively low temperatures as demonstrated in example 2. This ideology is similar to previous studies involving utilization of an incoming molecular beam flux of silicon. However, for wafer pacification, this is unsuitable as the deposited sacrificial material needs to be solid state and further, any deposited material will contaminate and oxidize when exposed to atmosphere, requiring an additional outer oxide layer as a protective layer against contaminants and loss of sacrificial silicon to oxidation. Thus, an alternative tri-layer structure shown in FIG. 5 is proposed as an alternative form of wafer pacification compared to the conventional single oxide layer, in which the sacrificial film thickness must provide sufficient material such that both native oxides decompose minimizing utilization of bulk wafer material. The thickness of the deposited sacrificial film (d_{film}), differentiated from the actual thickness of the sacrificial film depicted in FIG. 5 as thickness is lost during the second oxidation stage, can be readily calculated from equation (8), assuming that only SiO and SiO₂ are present in the native oxide, as:

$${d}_{film} = ( \frac{{m}_{Si} \times {p}_{ox}}{{p}_{Si} \times {m}_{ox}} ) ( {d}_{ox 1} \times {n}_{ox 1} + {d}_{ox 2} \times {n}_{ox 2} ) + {d}_{ox 2} [ {n}_{ox 2} ( \frac{{m}_{Si} \times {p}_{ox}}{{p}_{Si} \times {m}_{ox}} ) + ( 1 - {n}_{ox 2} ) ( \frac{{m}_{Si} \times {p}_{so}}{{p}_{Si} \times {m}_{so}} ) ] \qquad ( 8 )$$

wherein m, d, n, and p are the respective molecular weight, thickness, volumetric percentage and mass density of the various components, where ox and so represent the SiO₂ and SiO, respectively, and ox1 and ox2 are the interior and exterior oxide layers, respectively. The last term enclosed in square bracket accounts for the thickness of the deposited film loss to formation of the exterior oxide layer, wherein the first and second term enclosed by the first square bracket correspond to the necessary thickness of sacrificial silicon for decomposition of the interior and exterior oxide layers, respectively. Equation (2) assumes that during thermal decomposition process the SiO₂ will react rather with Si in the sacrificial film than with Si from the wafer because of different crystalline phases.

A series of experiments were performed on n-type Si(100) wafers with 2 nm air-formed native oxide layers (as measured by ellilpsometry), in which degreased samples were loaded into a pulsed laser deposition system that was baked and pumped over night until a base pressure of ˜10⁻⁷ Torr was obtained. At a substrate temperature of 200° C., significantly lower than necessary for reaction to occur, a thin silicon film was deposited onto the native oxide, in which film thickness was calibrated utilizing growth rates calculated from transmission electron microscopy. The deposited film and native oxide layer were both amorphous as indicated in-situ utilizing reflection high-energy electron diffraction (RHEED). The sample was subsequently removed from vacuum and stored under laboratory conditions (room temperature at atmosphere) for a period of ˜1 month in an attempt to allow the sacrificial silicon film to oxidize forming the exterior oxide layer. After aging, the samples were reloaded into the deposition chamber, pumped as before, and heated to 850° C. and held at that temperature for 30 minutes while RHEED was utilized to monitor the oxide desorption process. The samples were then rapidly cooled and removed from vacuum for ex-situ contact atomic force microscopy (AFM) measurements, in which a minimum of 3 locales were sampled.

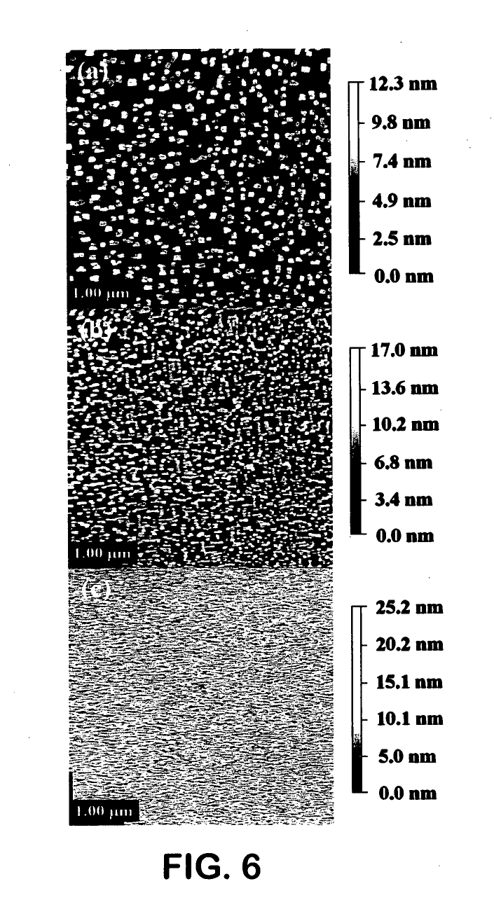

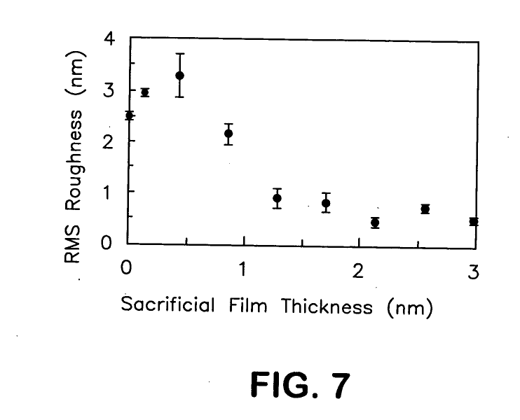

Three typical 5 μm scan results are shown in FIG. 6 for samples subjected to film thicknesses of 0.0 nm, 0.9 nm, and 1.3 nm. Further, the calculated RMS roughnesses for different sacrificial film thickness are shown in FIG. 7 with standard deviation error bars. For control samples subjected to no sacrificial film, FIG. 6(a), a surface characterized with small silicon clusters with typical peak-valley measurements of 8 nm is noticed and a calculated RMS roughness of 2.5 nm, consistent with other desorption experiments performed utilizing the same wafers. As the sacrificial film thickness is increased, the surface roughness increases, as expected to be contributed to a combination of factors, including but not limited to: (1) after the second oxidation step all sacrificial silicon has been utilized, effectively causing the net increase in the native oxide layer causing increased wafer etching; (2) thin sacrificial film thicknesses yielding incomplete coverage may allow preferential reaction of the oxides with the wafer increasing surface etching locally; (3) sacrificial film roughness transferring through the oxide to the wafer; and (4) uneven oxidation formation. However, at a treatment thickness of 0.9 nm, FIG. 2(b), a RMS roughness value of 2.1 nm is obtained indicating that the surface treatment has re-obtained the initial value for the normally desorbed sample resulting from overcoming the prior initially roughening factors. Further, at a treatment thickness of 1.3 nm, FIG. 6(c), the RMS roughness has decreased significantly to a value of 0.9 nm and further decreases to a minimum value of 0.4 nm at a deposited sacrificial film thickness of 2.1 nm.

RHEED results indicate minimum polycrystalline phases present on the sample subjected to a 1.3 nm sacrificial film, with samples with sacrificial film thicknesses up to 0.8 nm exhibiting 2× reconstruction along the [110] direction. Strong polycrystalline phases with diffuse scattering are present on samples subjected to 1.7 nm or thicker sacrificial films. By combined surface roughness and crystalline structure, the criteria for optimal sacrificial film thickness includes the minimization of surface roughness as measured with AFM, while maintaining a high crystalline surface as indicated with RHEED. Thus, there is a trade off with the minimum obtainable surface roughness and crystalline structure; however the 1.3 nm sample exhibits significant improvement in surface smoothness while maintaining crystalline structure, and is the optimal sacrificial film thickness.

In conclusion, a tri-layer wafer pacification technique indicates a significant reduction in surface roughness when thermally desorbed and results in a single crystalline surface.

### Example 4

This example is another demonstration of the application of the method of the invention to GaAs surfaces. This example describes an experiment where part of a substrate was masked in order to isolate the present inventions affect on pit formation.

A gallium arsenide substrate was degreased utilizing a series of ultrasonic baths in 1,1,1-trichloroethane, toluene, acetone, and methanol prior to the loading into a PLD chamber. The chamber was subsequently pumped overnight to reach a pressure of 8.2×10⁻⁷ Torr while the substrate temperature was 48° C. The shutter was then moved over half of the substrate and an amorphous layer of gallium arsenide was deposited by impinging a 248 nm KrF laser operating at 250 mJ with a repetition rate of 5 Hz onto a gallium arsenide target located 7 cm away from the substrate for 30 seconds. Following this deposition, the structure formed, as shown in FIG. 8, was heating slowly to 680° C. and held at temperature for 20 minutes, to ensure conditions that would normally result in surface pit formation. The substrate was then cooled at a relatively quick rate (greater than 1° C./second) to ensure that surface changes due to the cooling process are minimal. Once the sample reached a temperature of 70° C., the substrate was removed from the vacuum chamber and analyzed utilizing a Jeol 4210 AFM operating in contact mode, in which a 5 μm scan was taken.

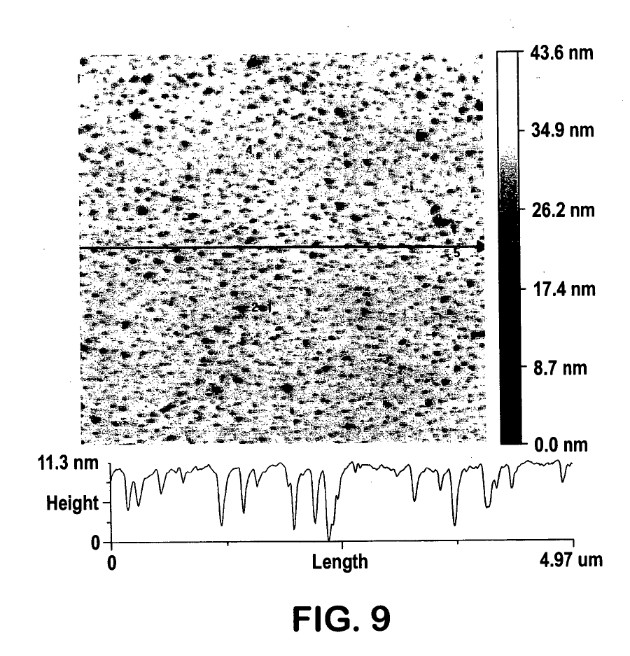

The sample was analyzed in 6 different places (3 samplings for each side of the substrate) in which 5 μm scans were taken. The average roughness, as defined by JIS B0601, was found to be 0.39 nm for the portion of the sample subjected to the present invention and 1.44 nm for the untreated portion. FIG. 9 shows a typical AFM image captured for the untreated portion of the substrate, with an average roughness of 1.55 nm. The line scan across the image profiles the commonly formed pits, which have depths and widths in the range of 10 nm and 100 nm, respectively. As can be seen by the scale of this line scan, the maximum change in height is 11.3 nm.

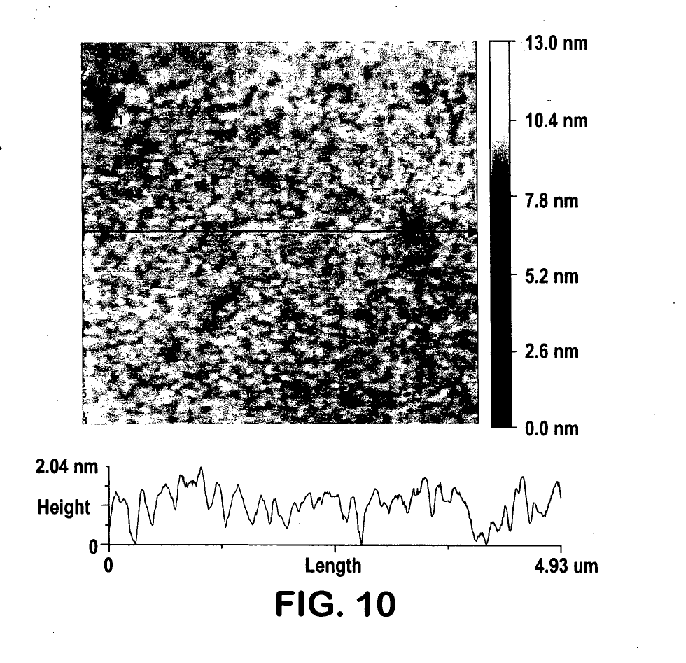

FIG. 10 shows a typical AFM image captured for the portion of the substrate treated to the present invention. The image shows no presence of large pits and is characterized by an average roughness of 0.33 nm. The line scan across the image shows the presence of a surface with a maximum change in height of 2.04 nm. The surface pits shown in FIG. 9 are not present on this portion of the sample and thus conclusively demonstrate the effectiveness of the present invention.

### Example 5

Following the results of Example 4, another experiment was performed to demonstrate the elimination of pit formation. As before, the gallium arsenide substrate was degreased and loaded into the PLD chamber and pumped overnight to reach a pressure of 7.5×10⁻⁷ Torr while the substrate temperature was 50° C. Gallium arsenide was subsequently deposited onto the substrate utilizing similar parameters as in Example 4, after which, the substrate was heated to a temperature of 650° C. and held for 20 minutes. Then, the sample was cooled as previously until a temperature of 84° C. was reached and it was subsequently removed from the vacuum chamber and analyzed utilizing the same AFM as before.

The sample was analyzed in a 5 μm scan, in which no pits were present on the surface, furthermore the average roughness, as defined by JIS B0601, was found to be 0.43 nm, again demonstrating the effectiveness of the present invention.

1. A method for removing a layer of native oxide from a surface of a substrate without significantly altering the smoothness of the said substrate surface, said method comprising:
1) depositing on said substrate surface a thin sacrificial layer of said substrate surface material, said deposited sacrificial layer substantially covering said native oxide layer, said deposited sacrificial layer having a thickness sufficient to react with all of said native oxide when said substrate surface is subjected to thermal oxide desorption conditions and said deposition being conducted under conditions that do not significantly affect the chemical or physical properties of said substrate or said substrate surface, and
2) subjecting said substrate to thermal oxide desorption conditions for a time sufficient for all of said native oxide layer to react with said deposited sacrificial layer of substrate material to form volatile reaction products and evaporate from said substrate surface.

2. The method of claim 1 wherein said thickness of said deposited sacrificial layer is proportional to the thickness and chemical composition of said native oxide layer.

3. The method of claim 1 wherein said deposited sacrificial layer is of a thickness to also react with any native oxide that has formed on the outer surface of said sacrificial layer before said substrate is subjected to said thermal oxide desorption.

4. The method of claim 2 or 3 wherein the thickness of said deposited sacrificial material is in the range of 0.1 to 100 nm.

5. The method of claim 1 wherein said substrate surface is a semiconductor.

6. The method of claim 5 wherein said semiconductor surface comprises silicon.

7. The method of claim 6 wherein the thickness, d_{film}, of the deposited sacrificial silicon is calculated from the equation:
d_{film}=0.48×d_{oxide}×n
where d_{oxide} is the total oxide thickness and n is the percentage of SiO₂ in the native oxide (assuming densities of 2.3 g/cm³ and 2.4 g/cm³ for amorphous silicon and SiO₂, respectively).

8. The method of claim 6 wherein said thermal oxide desorption is carried out at between about 700° C. and 900° C.

9. The method of claim 5 wherein said semiconductor surface is a group III-V alloy.

10. The method of claim 9 wherein said group III-V alloy is GaAs.

11. The method of claim 10 wherein the thickness, daum, of the deposited sacrificial GaAs is calculated from the equation:
$${d}_{film} = \frac{{d}_{oxide} \times {m}_{GaAs}}{{P}_{GaAs}} \times [ \frac{10 \times {p}_{{As}_{2} {O}_{5}} \times {n}_{{As}_{2} {O}_{5}}}{{m}_{{As}_{2} {O}_{5}}} + \frac{6 \times {p}_{{As}_{2} {O}_{3}} \times {n}_{{As}_{2} {O}_{3}}}{{m}_{{As}_{2} {O}_{3}}} + \frac{4 \times {p}_{{Ga}_{2} {O}_{3}} \times {n}_{{Ga}_{2} {O}_{3}}}{{m}_{{Ga}_{2} {O}_{3}}} + \frac{5 \times {p}_{{GaAsO}_{4}} \times {n}_{{GaAsO}_{4}}}{{m}_{{GaAsO}_{4}}} ]$$
where n, m and p are the volumetric percentage, molecular weight and mass density of each species, respectively and d_{oxide} is the total oxide thickness.

12. The method of claim 10 wherein said thermal oxide desorption is carried out at between about 550° C. and 700° C.

13. The method of claim 3 wherein said the deposited sacrificial layer is silicon.

14. The method of claim 13 wherein said the deposited sacrificial silicon is calculated from the equation:
$${d}_{film} = ( \frac{{m}_{Si} \times {p}_{ox}}{{p}_{Si} \times {m}_{ox}} ) ( {d}_{ox 1} \times {n}_{ox 1} + {d}_{ox 2} \times {n}_{ox 2} ) + {d}_{ox 2} [ {n}_{ox 2} ( \frac{{m}_{Si} \times {p}_{ox}}{{p}_{Si} \times {m}_{ox}} ) + ( 1 - {n}_{ox 2} ) ( \frac{{m}_{Si} \times {p}_{so}}{{p}_{Si} \times {m}_{so}} ) ]$$
